(19) United States
(12) Patent Application Publication
(10) Pub. No.: US 2012/0314171 A1
(43) Pub. Date: Dec. 13, 2012

(54) DISPLAY DEVICES HAVING ELECTROLESSLY PLATED CONDUCTORS AND METHODS

(75) Inventors: Anurag Jindal, Boise, ID (US); Kunal Parekh, Boise, ID (US); Prashant Raghu, Boise, ID (US); Nicolai Petrov, Boise, ID (US); Mark Meldrim, Boise, ID (US)

(73) Assignee: Micron Technology, Inc.

(21) Appl. No.: 13/155,810

(22) Filed: Jun. 8, 2011

(51) Int. Cl. G02F 1/1343; H01L 33/60; H01L 33/42

(52) U.S. Cl. 349/139; 438/30; 438/29; 257/E33.072; 257/E33.064

(57) ABSTRACT

In one or more embodiments, display devices having electrolessly plated conductors and methods are disclosed. One such embodiment is directed to a method of forming a reflective pixel array for a display device, including forming a plurality of conductive pads, each of the conductive pads corresponding to a reflective pixel, and electrolessly plating each of the conductive pads with a reflective conductor.

### FIELD

The present disclosure relates generally to display devices and, in particular, in one or more embodiments, the present disclosure relates to display devices having electrolessly plated conductors and methods.

### BACKGROUND

Projectors, such as picoprojectors, electronic viewfinders of digital cameras, displays of portable devices, such as personal digital assistants (PDAs) and mobile telephones, and the like sometimes employ image display systems (e.g., sometimes called virtual image display systems), such as liquid crystal display systems, e.g., ferroelectric liquid crystal display systems, nematic liquid crystal display systems, etc. Liquid crystal display systems may include a spatial light modulator, such as a reflective spatial light modulator, a light source for illuminating the spatial light modulator, and optics for directing light from the light source into the spatial light modulator and for directing certain portions of the light reflected from the spatial light modulator to a desired viewing area.

A reflective spatial modulator may include liquid crystal material, such as ferroelectric liquid crystal material, nematic liquid crystal material, or the like, e.g., between a common conductor (e.g., electrode) that is transparent to light, and an array of reflective conductors (e.g., electrodes) that may be referred to as reflective pixel electrodes, corresponding to pixels.

The state of the liquid, crystal material between a reflective conductor and the common electrode, and thus the state of the corresponding pixel, can be changed by changing an electric field in the liquid crystal material in response to changing a voltage differential between the reflective conductor and the common electrode. That is, the liquid crystal material can transmit the light reflected from the reflective conductor, and thus the corresponding pixel, when in one state (e.g., ON) and can restrict transmission of the light to the reflective conductor, and thus the corresponding pixel, when in another state (e.g., OFF). Selectively, changing the states of the pixels generates images that are directed to the desired viewing area. It will be appreciated that image quality may be impacted by the amount of light that is reflected from each pixel during the ON state, and thus the reflectivity of the respective reflective conductor.

For the reasons stated above, and for other reasons stated below which will become apparent to those skilled in the art upon reading and understanding the present specification, there is a need in the art for alternatives to reflective conductors in existing liquid crystal display systems and their formation.

### BRIEF DESCRIPTION OF THE DRAWINGS

FIG. 1 is an exploded perspective view, illustrating an image display system, according to an embodiment.

FIG. 2 is an exploded perspective view of an example of a reflective spatial modulator, according to another embodiment.

FIGS. 3A-3D are cross-sectional views of a portion of a reflective pixel array during various stages of fabrication, according to another embodiment.

### DETAILED DESCRIPTION

In the following detailed description, reference is made to the accompanying drawings that form a part hereof, and in which is shown, by way of illustration, specific embodiments. In the drawings, like numerals describe substantially similar components throughout the several views. Other embodiments may be utilized and structural, logical, chemical and electrical changes may be made without departing from the scope of the present disclosure. The following detailed description is, therefore, not to be taken in a limiting sense.

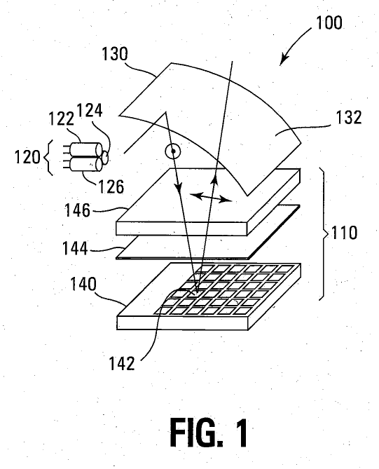

FIG. 1 is an exploded perspective view, illustrating an image display system 100, such as a liquid crystal image display system, e.g., a ferroelectric liquid crystal display system, nematic liquid crystal display system, etc. For example, image display system 100 may be a part of a projector, such as a picoprojector, an electronic viewfinder of digital camera, a display of a portable electronic device, such as personal digital assistant (PDA), a mobile telephone, or the like. Image display system 100 may include a reflective spatial light modulator 110 formed in accordance with embodiments of the present disclosure. For example, reflective spatial light modulator 110 may include electrolessly plated conductors. Image display system 100 may include a light source 120 for illuminating spatial light modulator 110 and optics 130 for directing light from the light source into spatial light modulator 110 and for transmitting light reflected from spatial light modulator 110 for display, such as by the projector, the electronic viewfinder, the display of a portable electronic device, etc.

Light source 120 may be a color light source that can generate multiple colors, e.g., red, blue, and green light. For example, light source may include a red light source 122, such as a red light emitting diode (LED), a blue light source 124, such as a blue LED, and a green light source 126, such as a green LED. Optics 130 may include a polarizing beam splitter 132 that reflects a portion of the light (e.g., about half) from light source 120 into reflective spatial light modulator 110 and that transmits light reflected from reflective spatial light modulator 110.

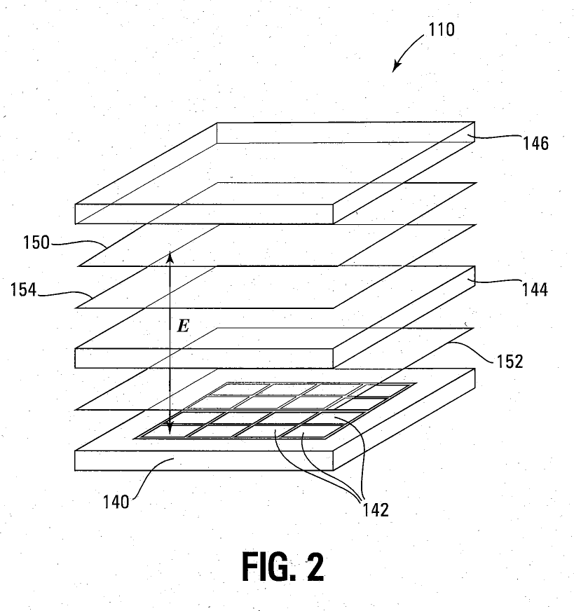

FIG. 2 is an exploded perspective view of an example of a reflective spatial modulator 110. Reflective spatial modulator 110 may include an array 140 of reflective pixel electrodes 142, each defining a pixel of reflective spatial light modulator 110 and of image display system 100. For example, each reflective pixel electrode 142 may correspond to a pixel of image display system 100 and of the finally displayed images generated by image display system 100.

Each reflective pixel electrode 142 may include a reflective conductor. For some embodiments, each reflective pixel electrode 142 may include an electrolessly formed, e.g., by electroless plating, electrically conductive reflective material (e.g., referred to herein as electroless conductive reflective material), according to the disclosed embodiments.

Liquid crystal material 144, such as ferroelectric liquid crystal material or nematic liquid crystal material, is over array 140, as shown in FIGS. 1 and 2. A transparent conductor 150, e.g., a common transparent conductor, may be over liquid crystal material 144 so that liquid crystal material 144 is between conductor 150 and array 140, as shown in FIG. 2. For example, transparent conductor 150 may be referred to as a transparent common electrode. For some embodiments, conductor 150 may be of indium tin oxide. A thickness of transparent material 146, such as a substantially clear glass plate, may be over conductor 150, and thus between polarizing beam splitter 132 and liquid crystal material 144, as shown in FIG. 1. Note that term “transparent” as used herein refers to something, e.g. transparent conductor 150 and transparent material 146, that permits transmission of at least a portion of one or more wavelengths of light.

An alignment material 152 may be between liquid crystal material 144 and array 140, and an alignment material 154 may be between liquid crystal material 144 and conductor 150, as shown in FIG. 2. Alignment materials 152 and 154 may act to orient the liquid crystal molecules in liquid crystal material 144 and provide boundary conditions for desired switching modes of liquid crystal material 144. Alignment materials 152 and 154 may be rubbed polymers, for example, and may have a series of grooves in their surfaces that act to orient the liquid crystal molecules.

A reflective pixel electrode 142 is in an ON state when a portion of liquid crystal material 144 adjacent to an reflective pixel electrode 142 allows light, received from polarizing beam splitter 132 and reflected from the reflective pixel electrode 142, to pass through the portion of liquid crystal material 144, as shown in FIG. 1. This may occur in response to producing a particular electric field E in the portion of liquid crystal material 144 adjacent to the reflective pixel electrode 142 by applying a voltage differential between conductor 150 and the reflective pixel electrode 142, e.g., by applying different voltages to conductor 150 and the reflective pixel electrode 142. The light may then pass through polarizing beam splitter 132 for display.

Changing the electric field E in the portion of liquid crystal material 144 adjacent to the reflective pixel electrode 142 causes the portion of liquid crystal material 144 adjacent to the reflective pixel electrode 142 to restrict (e.g., in some cases prevent) light from passing through to the reflective pixel electrode 142. This corresponds to the OFF state of the reflective pixel electrode 142. For example, electric field E may be changed by changing the voltage differential between conductor 150 and the reflective pixel electrode 142, such as by changing the voltage on the reflective pixel electrode 142 and leaving the voltage of conductor 150 as it was in the ON state.

For some embodiments, intermediate voltage differentials may be applied between conductor 150 and the reflective pixel electrode 142 to produce intermediate transmittances of the liquid crystal material 144, corresponding intermediate states of the reflective pixel electrode 142 between the OFF and ON states. For example, such intermediate states may be referred to as partially ON states of the reflective pixel electrode 142.

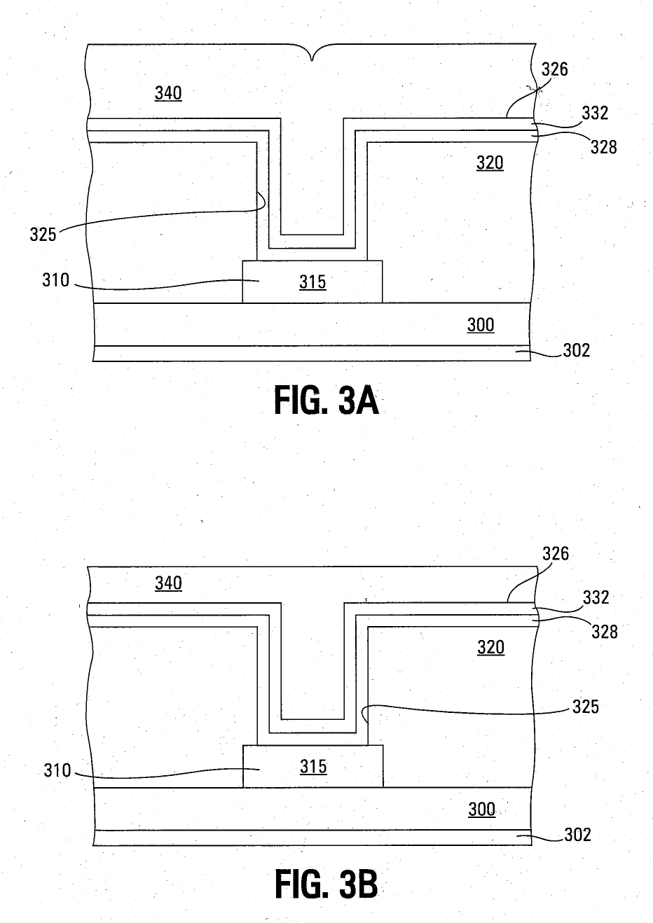

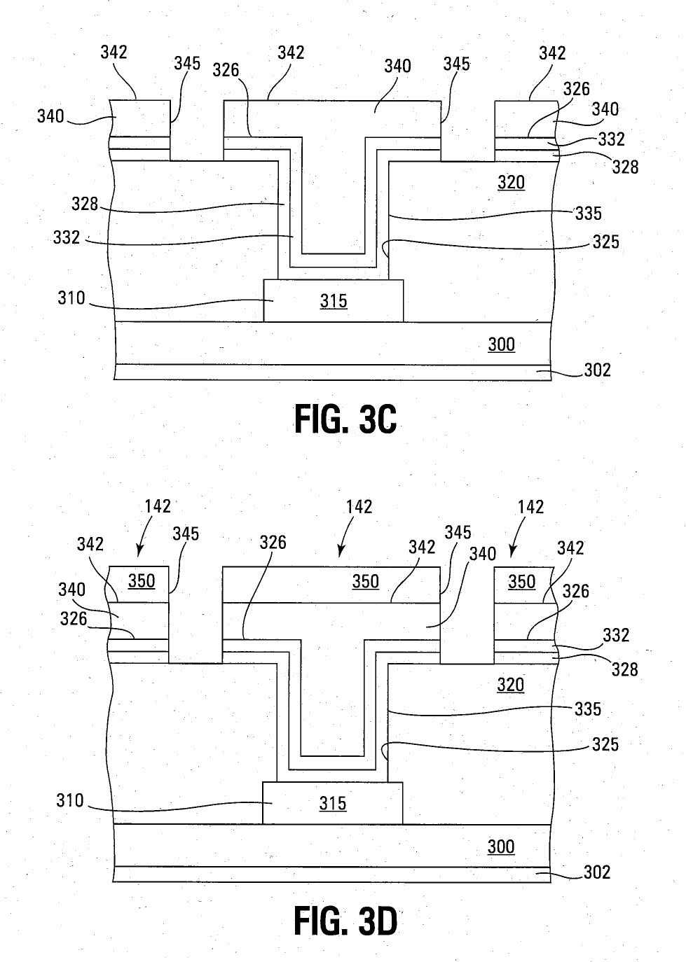

FIGS. 3A-3D are cross-sectional views of a portion of a reflective pixel array, such as a portion of the pixel array 140 of FIGS. 1 and 2, during various stages of fabrication. For some embodiments, a dielectric 300 may be formed over a substrate 302, such as a semiconductor, e.g., that may include silicon. Dielectric 300 is generally formed of one or more dielectric materials. For example, dielectric 300 may be formed from an oxide, e.g., silicon oxide, an oxynitride, e.g., silicon oxynitride, etc.

A conductive material 310 may be formed over dielectric 300. Conductive material 310 is generally formed of one or more conductive materials, and can include, for example, metals, such as aluminum, copper, etc. Regions of conductive material 310 may then be patterned for removal. For example, for some embodiments, a mask (not shown), e.g., imaging resist, such as photo-resist, may be formed over conductive material 310 and patterned to define regions of conductive material 310 for removal. The regions of conductive material 310 defined for removal are subsequently removed, e.g., by etching. Each remaining portion of conductive material 310 may form a conductor 315, where each conductor 315 may form a portion of a reflective pixel electrode, such as a reflective pixel electrode 142 shown in FIGS. 1 and 2.

A dielectric 320 (e.g., an interlayer dielectric) may then be formed over dielectric 300 and conductors 315. Dielectric 320 is generally formed of one or more dielectric materials. For example, dielectric 320 may be formed from an oxide, e.g., silicon oxide, an oxynitride, e.g., silicon oxynitride, etc.

Openings 325 (e.g., vias), one of which is shown in FIG. 3A, may then be formed by patterning dielectric 320 and removing portions of dielectric 320. For example, for some embodiments, a mask (not shown), e.g., imaging resist, such as photo-resist, may be formed over dielectric 320 and patterned to define regions of dielectric 320 for removal. The regions defined for removal are subsequently removed, e.g., by etching, to form openings 325 that may terminate on or within respective ones of conductors 315. That is, each opening 325 exposes at least a portion of a respective one of the conductors 315.

A conductive liner 326 may then optionally be formed over the upper surface of dielectric 320, over dielectric 320 within each opening 325, and over the exposed portion of the conductor 315 at the bottom of each opening 325. Conductive liner 326 is generally formed of one or more conductive materials. For example, conductive liner 326 may include a conductive material 328 and a conductive material 332 over conductive material 328.

Conductive material 328 may be formed over the upper surface of dielectric 320, over dielectric 320 within each opening 325, and over the exposed portion of the conductor 315 at the bottom of each opening 325. For example, conductive material 328 may be formed over portions of dielectric 320 that form the sidewalls of an opening 325 and the over the conductor 315 at the bottom of each opening 325. Conductive material 328 may act as an adhesion material and may be metal, such as titanium or any other conductive material suitable as an adhesion material to the underlying conductor 315. Conductive material 332 may then be formed over conductive material 328. Conductive material 332 may act as a barrier material and may be titanium nitride or any other conductive material suitable as a barrier material to restrict undesirable diffusion to underlying materials.

A conductive material 340 may then be formed over conductive material 332, e.g., using blanket deposition, so as to overfill openings 325. Conductive material 340 is generally formed of one or more conductive materials. Conductive material 340 may then be planarized, e.g., using chemical mechanical planarization (CMP), in FIG. 3B. Conductive material 340 may include substantially vertical portions that extend substantially vertically downward into openings 325 lined with liner 326 as shown in FIG. 3B. For some embodiments, the upper surface of conductive material 340 may be buffed as part of a buff CMP to reduce the roughness of the upper surface of conductive material 340. Buffing may act to increase the reflectivity of the resulting reflective pixel electrodes.

Conductive material 340 may be a metal or other conductive material that possesses the catalytic properties that support an auto-catalytic reaction used to electrolessly deposit (e.g., electrolessly plate) a conductive material (e.g., metal, such as silver, gold, cobalt, nickel, etc.) on conductive material 340. Non-limiting examples of conductive materials that possess suitable catalytic properties include tungsten, palladium, cobalt, etc.

Openings 345 (FIG. 3C) may then be formed by patterning conductive material 340 and removing portions of conductive material 340 and conductive liner 326 (e.g., conductive material 332 and conductive material 328) exposed by patterned conductive material 340. For example, for some embodiments, a mask (not shown), e.g., imaging resist, such as photo-resist, may be formed over conductive material 340 and patterned to define regions of conductive material 340 and conductive liner 326 for removal. The regions defined for removal are subsequently removed, e.g., by etching, to form the openings 345 that may respectively terminate on or within dielectric 320. The resulting structures of the patterned conductive material 340 may be referred to as conductors 342.

Openings 345 are between adjacent remaining portions of conductive material 340 (e.g., that form conductors 342, such as conductive pads), as shown in FIG. 3C. Each conductor 342 may form a portion of a reflective pixel electrode, where the openings 345 are between adjacent reflective pixel electrodes.

Each conductor 342 may be a unitary structure and may have a substantially “T”-shaped profile with a substantially vertical (e.g., vertical) portion that extends substantially vertically downward (e.g., vertically downward) within openings 325 lined with portions of liner 326 and a contiguous substantially horizontal (e.g., horizontal) portion of the same material as the substantially vertical portion that provides a substantially horizontal (e.g., horizontal) upper surface, as shown in FIG. 3C. For example, the substantially vertical portion of each conductor 342 may form a portion of a via plug extending substantially vertically downward (e.g., vertically downward) through dielectric 320 within an opening 325, as shown in FIG. 3C. The via plug may include a remaining portion of conductive liner 326 adjacent to the substantially vertical portion of the substantially vertical portion of the respective conductor 342.

Each conductor 342 may be electrically and physically coupled to a respective one of conductors 315 by a conductor formed from portions of conductive liner 326. Note that openings 345 are between adjacent remaining portions of conductive liner 326 and that each remaining portion of conductive liner 326 may form a conductor 335, including a remaining portion of conductive material 332, e.g., a barrier conductor, and a remaining portion of conductive material 328, e.g., an adhesion conductor, of a reflective pixel electrode. For some embodiments, each conductor 342 may be taken to include a conductor 335.

A reflective conductor 350 may then be selectively formed on (e.g., in direct physical contact with) an upper (e.g., substantially horizontal) surface of each of conductors 342, as shown in FIG. 3D. The reflective conductor 350 may be formed from a reflective conductive material, e.g., metal, such as silver, gold, cobalt, nickel, etc. For example, each conductor 342 may be electrolessly (e.g., autocatalytically) plated with the reflective conductive material of reflective conductor 350. As such, each conductor 350 may be referred to as an electroless (e.g., auto-catalytic) conductor to differentiate conductor 350 from conductors formed by other methods, such as physical vapor deposition (PVD), chemical vapor deposition (CVD), etc. For some embodiments, a conductor 350 of silver, gold, cobalt, or nickel may electrolessly plate a conductor 342 of tungsten or palladium, and for other embodiments, a conductor 350 of silver, gold, or nickel may electrolessly plate a conductor 342 of cobalt. Note that electroless plating is a non-galvanic-type plating process.

An upper surface of each conductor 350 may form an upper reflective surface of a reflective pixel electrode 142. Each reflective pixel electrode 142 may include an electroless conductor 350 over (e.g., in direct physical contact with) a conductor 342. Each conductor 342 may be over (e.g., in direct physical contact with) a conductor 335 that may be over (e.g., in direct physical contact with) a conductor 315. Each conductor 350 may be electrically and physically coupled to a conductor 315 by conductors 342 and 335, as shown in FIG. 3D. For other embodiments, each conductor 342 may include conductor 335. Openings 345 may electrically isolate adjacent pixel electrodes 142 from each other.

Each conductor 315, and thus each pixel electrode 142, may be selectively electrically coupled to one or more voltage sources (not shown). For some embodiments, each pixel electrode 142 may be selectively coupled to first and second voltage sources for selectively applying a first voltage of the first voltage source or a second voltage of the second voltage source to the respective pixel electrode 142. For example, selectively applying the first voltage to the respective pixel electrode 142 may turn the respective pixel 142 ON, e.g., while common conductor 150 is coupled to a third voltage source, and selectively applying the second voltage to the respective pixel 142 may turn the respective pixel 142 OFF, e.g., while common conductor 150 is coupled to the third voltage source. For some embodiments, common conductor 150 may remain at a fixed voltage, e.g., the voltage of the third voltage source, while the first and second voltages are selectively applied to the respective pixel electrode 142. Alternatively, for other embodiments, each pixel electrode 142 may be electrically coupled to a variable voltage source configured to selectively apply the first and second voltages or other intermediate voltages between the first and second voltages. For example, the intermediate voltages may produce partially ON states of the pixel electrode.

Array 140 may be tuned to a particular light source 120. In order to tune array 140 to a particular light source 120, conductors 350 may be formed from a material that reflects better for a particular colored light of light source 120 to compensate for a light source deficient in the particular colored light. For example, if red light source 122 is known to be weaker than blue light source 124 and green light source 126 (FIG. 1), conductors 350 might be formed from electroless gold, in that electroless gold can reflect red light better than green and blue light.

Conductor 350 may have a thickness in the range from 200 to 1000 angstroms. For other embodiments, conductor 350 may have a thickness in the range from 300 to 700 angstroms. For thicknesses of a silver conductor 350 less than about 200 angstroms, the reflectivity of the silver conductor 350 on a tungsten conductor 342 may be reduced for incident red, blue, or green light, owing to the effect of the underlying tungsten conductor 342. For a thickness of a silver conductor 350 greater than about 1000 angstroms, the reflectivity of the silver conductor 350 on a tungsten conductor 342 may be reduced for incident blue light and incident green light. For a thickness of a silver conductor 350 greater than about 1000 angstroms, the reflectivity, of the silver conductor 350 on a tungsten conductor 342 for incident red light may be less than or about the same as the reflectivity a silver conductor 350 with a thickness in the range from 200 to 1000 angstroms on a tungsten conductor 342.

For thicknesses of a conductor 350 above about 1000 angstroms, the openings 345 between pixel electrodes 142 may be too deep. For example, liquid crystal material 144 or alignment material 152 with liquid crystal material 144 thereover (FIG. 2) may deform into openings 345. However, when openings 345 are too deep the deformation may be excessive, impacting the performance of the pixel array.

Moreover, the electroless plating time is longer for larger thicknesses of conductor 350. This may cause excessive amounts of the conductive material of conductor 350 to form on the sides of conductor 342 within openings 345, thus increasing the likelihood of shorts between adjacent pixel electrodes 142, e.g., when the thickness is greater than about 1000 angstroms.

Electrolessly plating conductors 342 with electroless conductor 350 after forming the individual conductors 342 (e.g., after forming openings 345) avoids a need to first form conductor 350, e.g., with PVD or CVD, over conductor 342 and subsequently removing portions of conductor 350 and conductor 342 under conductor 350, e.g., by etching, to form the individual pixels. Therefore, electrolessly plating conductors 342 with electroless conductor 350 after forming the individual conductors 342 can facilitate a reduction (e.g., substantial elimination) of rough edges that can form on conductors 350 due to etching, and thus the uneven pixel edges that can result from the rough edges of conductors 350.

### CONCLUSION

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments.

What is claimed is:

1. A method of forming a reflective pixel array for a display device, comprising:
forming a plurality of conductive pads, each of the conductive pads corresponding to a reflective pixel; and
electrolessly plating each of the conductive pads with a reflective conductor.

2. The method of claim 1, wherein forming the plurality of conductive pads comprises forming each of the conductive pads, at least in part, from a conductive material selected from the group consisting of tungsten, palladium, and cobalt.

3. The method of claim 1, wherein electrolessly plating each of the conductive pads with a reflective conductor comprises electrolessly plating each of the conductive pads with a reflective conductor selected from the group consisting of silver, gold nickel, and cobalt.

4. The method of claim 1, wherein forming the plurality of conductive pads comprises patterning a conductive material and removing portions of the conductive material to form the conductive pads from remaining portions of conductive material.

5. The method of claim 4, further comprising buffing the conductive material before patterning the conductive material.

6. The method of claim 1, wherein electrolessly plating each of the conductive pads with a reflective conductor comprises electrolessly plating each of the conductive pads with a reflective conductor of a material that reflects light of a particular color better than light of other colors to compensate for a light source deficient in light of the particular color.

7. A method of forming a display device, comprising:
forming a plurality of first conductors, each first conductor corresponding to a reflective pixel of the display device;
forming a dielectric over the first conductors;
forming a plurality of second conductors over the dielectric and over the first conductors so that each of the second conductors is electrically coupled to a respective one of the first conductors; and
electrolessly plating each of the second conductors with a reflective third conductor.

8. The method of claim 7, further comprising patterning the dielectric to expose portions of the first conductors before forming the second conductors.

9. The method of claim 7, wherein forming the plurality of second conductors comprises forming the plurality of second conductors selected from the group consisting of tungsten and palladium, and wherein electrolessly plating each of the second conductors with a reflective third conductor comprises electrolessly plating each of the second conductors with a reflective third conductor selected from the group consisting of silver, gold, nickel, and cobalt.

10. The method of claim 7, wherein forming the plurality of second conductors comprises forming the plurality of second conductors from cobalt, and wherein electrolessly plating each of the second conductors with a reflective third conductor comprises electrolessly plating each of the second conductors with a reflective third conductor selected from the group consisting of silver, gold, and nickel.

11. The method of claim 7, further comprising selectively coupling each of the first conductors to receive one or more voltages.

12. The method of claim 7, further comprising coupling each of the first conductors to a variable voltage source.

13. The method of claim 7, further comprising placing liquid crystal material over the reflective third conductors.

14. The method of claim 13, further comprising placing a transparent fourth conductor over the liquid crystal material.

15. The method of claim 14, further comprising placing alignment material between the fourth conductor and the liquid crystal material and/or between the reflective third conductors and the liquid crystal material.

16. The method of claim 7, wherein forming a plurality of second conductors over the second dielectric and over the first conductors so that the each second conductor is electrically coupled to a respective one of the first conductors comprises forming a portion of each of the second conductors in an opening through the second dielectric that exposes a respective one of the first conductors.

17. The method of claim 7, wherein forming the plurality of second conductors comprises forming each of the second conductors from more than one conductive material.

18. A method of forming a display device, comprising:
forming a first conductive material over a first dielectric;
removing portions of the first conductive material to form a plurality of first conductors from remaining portions of the first conductive material;
forming a second dielectric over the first dielectric and the plurality of first conductors;
forming openings through the second dielectric to expose respective ones of the first conductors;
forming a conductive liner over the second dielectric and over each of the exposed first conductors;
forming a second conductive material over the conductive liner;
buffing an upper surface of second conductive material;
after buffing the upper surface of second conductive material, removing portions of the second conductive material and portions of the conductive liner, stopping on or within the second dielectric to form a plurality of conductive pads from remaining portions of the second conductive material and the conductive liner; and
electrolessly plating each of the conductive pads with a reflective third conductor.

19. The method of claim 18, further comprising placing liquid crystal material over the reflective third conductors, wherein the liquid crystal material is selected from the group consisting of ferroelectric liquid crystal material and nematic liquid crystal material.

20. The method of claim 19, further comprising placing a conductor of indium tin oxide over the liquid crystal material.

21. A reflective pixel array for a display device, comprising:
a plurality of reflective pixel electrodes, each reflective pixel electrode comprising a conductive pad electrolessly plated with conductive reflective material.

22. The reflective pixel array of claim 21, wherein each of the conductive pads comprises a material selected from the group consisting of tungsten and palladium and is electrolessly plated with a conductive reflective material selected from the group consisting of silver, gold, nickel, and cobalt.

23. The reflective pixel array of claim 21, wherein each the conductive pads comprises cobalt and is electrolessly plated with a conductive reflective material selected from the group consisting of silver, gold, and nickel.

24. The reflective pixel array of claim 21, wherein conductive reflective material has a thickness in the range from 200 to 1000 angstroms.

25. The reflective pixel array of claim 24, wherein conductive reflective material has a thickness in the range from 300 to 700 angstroms.

26. A liquid crystal display device, comprising:
an array of reflective pixel electrodes, at least one of the reflective pixel electrodes comprising:
a first conductor;
a dielectric over the first conductor;
a second conductor over the dielectric and first conductor, and electrically coupled to the first conductor; and
an electroless reflective conductive material over and in direct contact with an upper surface of the second conductor;
liquid crystal material over the array of reflective pixel electrodes; and
a transparent electrode over the liquid crystal material.

27. The liquid crystal display device of claim 26, wherein the electroless reflective conductive material comprises silver and the second conductor comprises tungsten.

28. The liquid crystal display device of claim 26, wherein the electroless reflective conductive material consists essentially of silver.

29. The liquid crystal display device of claim 26, wherein the liquid crystal material comprises a ferroelectric liquid crystal material.

30. The liquid crystal display device of claim 26, wherein the second conductor comprises a substantially vertical portion that forms a portion of a via plug that extends through the dielectric and that is coupled to the first conductor.

31. The liquid crystal display device of claim 30, wherein the via plug further comprises a conductive liner adjacent to the substantially vertical portion of the second conductor.

32. The liquid crystal display device of claim 31, wherein the conductive liner comprises barrier material adjacent to the second conductor and adhesion material between the dielectric and the barrier material.
